(19) United States
(12) Patent Application Publication
(10) Pub. No.: US 2025/0214124 A1
(43) Pub. Date: Jul. 3, 2025

(54) SUBSTRATE PROCESSING APPARATUS AND SUBSTRATE PROCESSING METHOD

(71) Applicant: Semes Co., Ltd, Cheonan-si (KR)

(72) Inventors: In Ki JUNG, Hwaseong-si (KR); Jun Ho SONG, Hwaseong-si (KR); Jae Youl KIM, Yongin-si (KR); Ho Jong HWANG, Hwaseong-si (KR); Won Geun KIM, Goyang-si (KR)

(73) Assignee: Semes Co., Ltd, Cheonan-si (KR)

(21) Appl. No.: 19/005,208

(22) Filed: Dec. 30, 2024

(30) Foreign Application Priority Data
Dec. 29, 2023 (KR) 10-2023-0196035

(51) Int. Cl. B08B 15/02; B08B 3/04; B08B 3/08; B08B 5/00; B08B 13/00; H01L 21/67

(52) U.S. Cl. CPC B08B 15/02; B08B 3/041; B08B 3/08; B08B 5/00; B08B 13/00; B08B 2215/003; H01L 21/67051

(57) ABSTRACT

Disclosed is a substrate processing apparatus and a substrate processing method that are capable of appropriately exhausting impurities, such as fumes, generated during substrate treatment. A housing providing an inner space; a cup body that is provided in the inner space and has a treatment space with an open top; a support unit for supporting a substrate in the treatment space; an airflow supply unit installed on an upper wall of the housing and supplying descending airflow to the inner space and the treatment space; a lifting unit for changing a relative height between the substrate supported by the support unit and the cup body; a liquid supply unit for supplying a treatment liquid to the substrate supported by the support unit; an exhaust member for exhausting the inner space and the treatment space; and a partition plate that divides the inner space into an upper space and a lower space and may be provided to be movable in an up and down direction.

### CROSS-REFERENCE TO RELATED APPLICATIONS

This application claims priority to and the benefit of Korean Patent Application No. 10-2023-0196035 filed in the Korean Intellectual Property Office on Dec. 29, 2023, the entire contents of which are incorporated herein by reference.

### TECHNICAL FIELD

The present invention relates to a substrate processing apparatus and a substrate processing method, and more specifically, a substrate processing apparatus and a substrate processing method that are capable of improving a speed of replacing an atmosphere of an inner space by reducing an upper space of a housing.

### BACKGROUND ART

A semiconductor process includes a process of cleaning a thin film, foreign substances, particles, and the like on a substrate. These processes are accomplished by placing a substrate on a spin head with a patterned side facing up or down, supplying a treatment liquid to the substrate while the spin head is rotated, and subsequently drying the wafer.

An acidic solution may be used as the treatment liquid. The acidic solution removes thin films, foreign substances, particles, etc. remaining on the substrate. Thereafter, the acidic solution is replaced with pure water, and the pure water is replaced with isopropyl alcohol (IPA) again after removing the acidic solution on the substrate. Thereafter, IPA is dried.

The substrate is treated in a housing. An airflow supply unit is provided on an upper wall of the housing. The airflow supply unit controls the atmosphere of the inner space of the housing. According to an example, while drying the IPA, drying gas is supplied to form a drying atmosphere. In addition, descending airflow is supplied onto the substrate so that impurities, such as fumes, generated from the substrate do not flow out and are exhausted. However, since the inner space of the housing is provided relatively larger than the treatment space of processing the substrate, a lot of time is required to control the atmosphere of the inner space. In addition, there is a problem that the descending airflow toward the substrate is not sufficiently supplied, and fumes generated during the substrate treatment are not properly exhausted.

### SUMMARY OF THE INVENTION

The present invention has been made in an effort to a substrate processing apparatus and a substrate processing method capable of appropriately exhausting impurities, such as fumes, generated during substrate treatment.

The present invention has also been made in an effort to a substrate processing apparatus and a substrate processing method capable of quickly replacing an atmosphere of an inner space when processing a substrate.

The present invention has also been made in an effort to a substrate processing apparatus and a substrate processing method capable of suppressing the generation of impurities, such as particles, during drying IPA on the substrate.

The problem to be solved by the present invention is not limited to the above-mentioned problems, and the problems not mentioned will be clearly understood by those skilled in the art from the descriptions below.

An exemplary embodiment of the present invention provides, an apparatus of processing a substrate, the apparatus comprising: a housing providing an inner space; a cup body that is provided in the inner space and has a treatment space with an open top; a support unit for supporting a substrate in the treatment space; an airflow supply unit installed on an upper wall of the housing and supplying descending airflow to the inner space and the treatment space; a lifting unit for changing a relative height between the substrate supported by the support unit and the cup body; a liquid supply unit for supplying a treatment liquid to the substrate supported by the support unit; an exhaust member for exhausting the inner space and the treatment space; and a partition plate that divides the inner space into an upper space and a lower space and may be provided to be movable in an up and down direction.

According to the exemplary embodiment of the present invention, the partition plate is fixedly installed on an outer wall of the cup body to be raised and lowered together with the cup body, and may be extends from the outer wall of the cup body toward a sidewall of the housing.

According to the exemplary embodiment of the present invention, a passage through which the descending airflow flows may be formed between the partition plate and the sidewall of the housing.

According to the exemplary embodiment of the present invention, the partition plate may be provided as a blocking plate in which a hole penetrating the partition plate vertically is not formed.

According to the exemplary embodiment of the present invention, the partition plate may be provided in a ring shape.

According to the exemplary embodiment of the present invention, the airflow supply unit is provided to selectively supply descending airflow of first gas and descending airflow of second gas, the second gas is gas with lower humidity than the first gas, the liquid supply unit includes: a first nozzle that supplies a first treatment liquid; and a second nozzle that supplies a second treatment liquid, and the apparatus further may include a controller for controlling the airflow supply unit, the liquid supply unit, and the lifting unit.

According to the exemplary embodiment of the present invention, when the liquid supply unit discharges the first treatment liquid, the controller positions the partition plate at a first position and controls the liquid supply unit, the lifting unit, and the airflow supply unit to supply the descending airflow of the first gas, and when the liquid supply unit discharges the second treatment liquid, the controller positions the partition plate at a second position, and controls the liquid supply unit, the lifting unit, and the airflow supply unit to supply the descending airflow of the second gas, and the second position may be higher than the first position.

According to the exemplary embodiment of the present invention, the first treatment liquid is acidic chemical or pure water, and the second treatment liquid may be an organic solvent.

According to the exemplary embodiment of the present invention, the organic solvent may be isopropyl alcohol.

According to the exemplary embodiment of the present invention, the apparatus may further include an auxiliary cup surrounding the cup body and having an open top, wherein the partition plate is fixedly installed on an outer wall of the auxiliary cup so as to be raised and lowered together with the auxiliary cup, and extends from the outer wall of the auxiliary cup toward a sidewall of the housing, and the lifting unit may raises and lowers the auxiliary cup.

According to the exemplary embodiment of the present invention, the controller may further include when the liquid supply unit discharges the first treatment liquid, the controller positions the partition plate at a first position and controls the liquid supply unit, the lifting unit, and the airflow supply unit to supply descending airflow of first gas, and when the liquid supply unit discharges the second treatment liquid, the controller positions the partition plate at a second position, and controls the liquid supply unit, the lifting unit, and the airflow supply unit to supply descending airflow of second gas, and the second position may be higher than the first position.

According to the exemplary embodiment of the present invention, the auxiliary cup may be coupled to the cup body.

An exemplary embodiment of the present invention provides, a method of processing a substrate by using the apparatus of processing the substrate of claim 1, the method comprising: a first treatment operation of liquid-treating a substrate in a state where descending airflow of first gas is supplied; and a second treatment operation of liquid-treating the substrate in a state where descending airflow of second gas is supplied, the second gas is gas with lower humidity than the first gas, and a position of the partition plate may be adjusted so that a volume of the upper space provided during the second treatment operation is smaller than a volume of the first treatment operation.

According to the exemplary embodiment of the present invention, the partition plate may be fixedly installed on the cup body so as to be raised and lowered together with the cup body.

According to the exemplary embodiment of the present invention, the apparatus further includes an auxiliary cup surrounding the cup body and having an open top, the partition plate is fixedly installed on an outer wall of the auxiliary cup and may be adjusted in position by being raised and lowered together with the auxiliary cup.

According to the exemplary embodiment of the present invention, in the first treatment operation, the liquid is acidic chemical or pure water, and in the second treatment operation, the liquid may be an organic solvent.

An exemplary embodiment of the present invention provides, an apparatus of processing a substrate, the apparatus comprising: a housing providing an inner space; a cup body that is provided in the inner space and has a treatment space with an open top; a support unit for supporting a substrate in the treatment space; an airflow supply unit installed on an upper wall of the housing and supplying descending airflow to the inner space and the treatment space; a lifting unit for changing a relative height between the substrate supported by the support unit and the cup body; a liquid supply unit for supplying a treatment liquid to the substrate supported by the support unit; an exhaust member for exhausting the inner space and the treatment space; a partition plate that divides the inner space into an upper space and a lower space and is provided to be movable in an up and down direction; and a controller for controlling the airflow supply unit, the liquid supply unit, and the lifting unit, the partition plate is provided in a ring shape, is fixedly installed on an outer wall of the cup body to be raised and lowered together with the cup body, extends from the outer wall of the cup body toward a sidewall of the housing, and is formed with a passage through which the descending airflow flows between the partition plate and the sidewall of the housing, the liquid supply unit includes: a first nozzle that supplies a first treatment liquid; and a second nozzle that supplies a second treatment liquid, and the airflow supply unit is provided to selectively supply descending airflow of first gas and descending airflow of second gas, the second gas may be gas with lower humidity than the first gas.

According to the exemplary embodiment of the present invention, the controller may further include when the liquid supply unit discharges the first treatment liquid, the controller positions the partition plate at a first position and controls the liquid supply unit, the lifting unit, and the airflow supply unit to supply the descending airflow of the first gas, and when the liquid supply unit discharges the second treatment liquid, the controller positions the partition plate at a second position, and controls the liquid supply unit, the lifting unit, and the airflow supply unit to supply the descending airflow of the second gas, and the second position may be higher than the first position.

According to the exemplary embodiment of the present invention, wherein the first treatment liquid is acidic chemical or pure water, and the second treatment liquid may be an organic solvent.

According to the exemplary embodiment of the present invention, the apparatus may further include an auxiliary cup surrounding the cup body and having an open top, wherein the auxiliary cup is coupled to the cup body, the partition plate is fixedly installed on an outer wall of the auxiliary cup, and extends from the outer wall of the auxiliary cup toward the sidewall of the housing, and when the liquid supply unit discharges the first treatment liquid, the controller positions the partition plate at a first position and controls the liquid supply unit, the lifting unit, and the airflow supply unit to supply the descending airflow of the first gas, and when the liquid supply unit discharges the second treatment liquid, the controller positions the partition plate at a second position, and controls the liquid supply unit, the lifting unit, and the airflow supply unit to supply the descending airflow of the second gas, and the second position is higher than the first position, the first treatment liquid is acidic chemical or pure water, and the second treatment liquid may be an organic solvent.

According to the exemplary embodiment of the present invention, the present invention may appropriately exhaust impurities, such as fumes, generated during substrate treatment.

Further, according to the exemplary embodiment of the present invention, the present invention may quickly replace the atmosphere of the inner space when treating the substrate.

Furthermore, according to the exemplary embodiment of the present invention, the present invention may suppress the generation of impurities, such as particles, when drying IPA on a substrate.

The effect of the present invention is not limited to the foregoing effects, and those skilled in the art may clearly understand non-mentioned effects from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view schematically illustrating a substrate processing apparatus according to an exemplary embodiment of the present invention.

FIG. 2 is a diagram schematically illustrating an exemplary embodiment of a liquid treating chamber of FIG. 1.

FIG. 3 is a flowchart illustrating a substrate processing method according to an exemplary embodiment of the present invention.

FIG. 4 is a cross-sectional view illustrating a cross-section of the liquid treating chamber in a first treatment operation.

FIG. 5 is a cross-sectional view illustrating a cross-section of the liquid treating chamber in a second treatment operation.

FIG. 6 is a diagram schematically illustrating a liquid treating chamber according to another exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

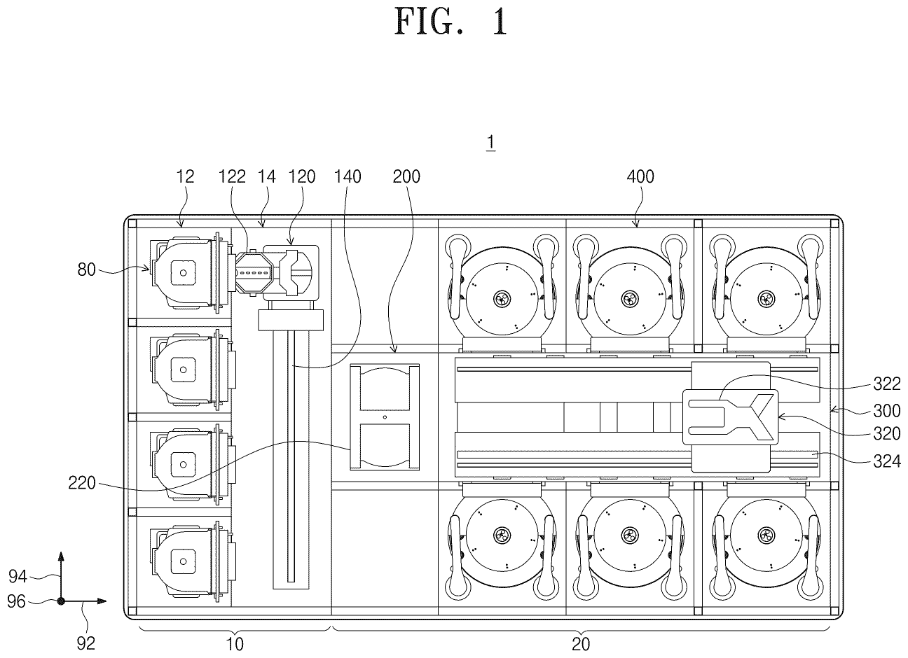

Hereinafter, exemplary embodiments of the present invention will be described with reference to the accompanying drawings. FIG. 1 is a top plan view schematically illustrating a substrate processing apparatus according to an exemplary embodiment of the present invention.

Referring to FIG. 1, a substrate processing apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the up and down direction, and the hands 122 may move forwardly and backwardly independently of each other.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on both sides of the transfer chamber 300. At each of both sides of the transfer device 300, the liquid treating devices 400 may be provided in an array of A×B (each of A and B is 1 or a natural number larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. A plurality of hands 322 are provided to be spaced apart in the up and down direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

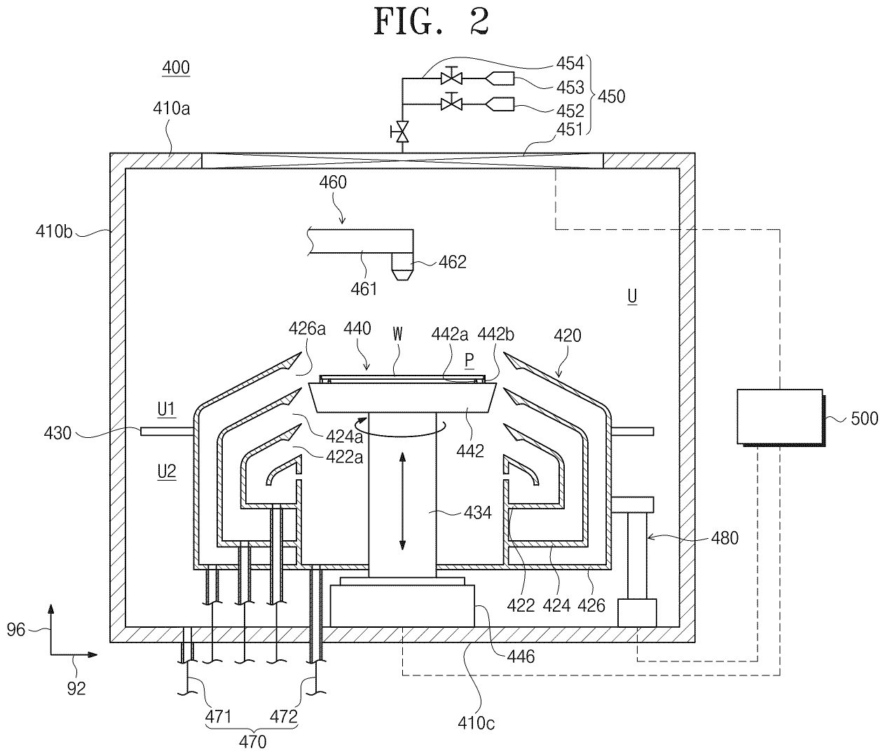

FIG. 2 is a diagram schematically illustrating an exemplary embodiment of a liquid treating chamber of FIG. 1. Referring to FIG. 2, the liquid treating chamber 400 includes a housing 410, a cup body 420, a partition plate 430, a support unit 440, an airflow supply unit 450, a liquid supply unit 460, an exhaust unit 470, a lifting unit 480, and a controller 500.

The housing 410 is provided in a generally rectangular parallelepiped shape. The housing 410 provides an inner space U. The cup body 420, the partition plate 430, the support unit 440, and the liquid supply unit 460 are disposed in the inner space U. The airflow supply unit 450 is provided on an upper wall 410b of the housing 410.

The cup body 420 has a treatment space P with an open top, and the substrate W is liquid-treated in the treatment space P. The supporting unit 440 supports the substrate W in the treatment space P. The liquid supply unit 460 supplies the liquid onto the substrate W supported by the support unit 440. A plurality of types of liquid may be provided, and may be sequentially supplied onto the substrate W. The lifting unit 480 adjusts a relative height between the cup body 420 and the supporting unit 440.

According to the example, the cup body 420 includes a plurality of cups 422, 424, and 426. Each of the cups 422, 424, and 426 has a recovery space for recovering a liquid used to process the substrate. Each of the cups 422, 424, and 426 is provided in the shape of a ring that surrounds the support unit 440. When the liquid treatment process is in progress, the treatment liquid scattered by the rotation of the substrate W is introduced into the recovery space through inlets 422a, 424a, and 426a of the respective cups 422, 424, and 426. According to the example, the cup body 420 includes an inner cup 422, an intermediate cup 424, and an outer cup 426. The inner cup 422 is disposed to surround the support unit 440, the intermediate cup 424 is disposed to surround the inner cup 422, and the outer cup 426 is disposed to surround the intermediate cup 424. A second inlet 424a through which the liquid flows into the intermediate cup 424 may be located above a first inlet 422a through which the liquid flows into the inner cup 422, and a third inlet 426a through which the liquid flows into the outer cup 426 may be located above the second inlet 424a.

The partition plate 430 divides the inner space U into an upper space U1 and a lower space U2. The partition plate 430 is located outside the outer cup 426. The partition plate 430 extends in a direction from the outer cup 426 toward a sidewall 410a of the housing 410. A passage 431 through which descending airflow flows is formed between the partition plate 430 and the sidewall 410b of the housing 410. According to the example, the partition plate 430 is provided in a ring shape. Further, the partition plate 430 may be installed on the sidewall 426b of the outer cup 426.

The support unit 440 includes a support plate 442 and a driving shaft 444. An upper surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. A drive shaft 444 is driven by a driver 446, is connected to the center of the bottom surface of the substrate W, and rotates the support plate 442 with respect to the central axis thereof.

The airflow supply unit 450 is installed on the upper wall 410a of the housing 410. The airflow supply unit 450 supplies descending airflow to the inner space U and the treatment space P. The airflow supply unit 450 includes a fan 451, a first gas supply source 452, a second gas supply source 453, and a gas supply line 454. The fan 451 forms descending airflow in the inner space U. The descending airflow descends from an upper portion to a lower portion of the inner space U. The descending airflow may pass through the substrate W supported by the support unit 440. The descending airflow is exhausted to the outside of the housing 410 through the exhaust unit 470. The first gas supply source 452 supplies first gas. According to the example, the first gas may be inert gas, air, or nitrogen. The second gas supply source 453 supplies second gas. The second gas may be gas that contains less moisture than the first gas. The second gas may be gas that does not contain moisture. The gas supply line 454 connects each of the first gas supply source 452 and the second gas supply source 453 to the fan 451. A valve for adjusting the supply of the first gas and the second gas may be installed in the gas supply line 454.

The liquid supply unit 460 includes a first nozzle 462 and a second nozzle 464. The first nozzle 462 supplies a first treatment liquid onto the substrate W. According to the example, the first treatment liquid may be an acidic chemical or water. The acidic chemical may be an aqueous phosphoric acid solution, an aqueous sulfuric acid solution, or a hydrogen fluoride solution. The water may be pure water or deionized water. The second nozzle 464 supplies a second treatment liquid onto the substrate W. According to the example, the second treatment liquid may be an organic solvent. The organic solvent may be isopropyl alcohol (IPA). Optionally, the liquid supply unit may further include one or more nozzles in addition to the first nozzle 462 and the second nozzle 464. Additional nozzles may supply different types of treatment liquids to the substrate.

The first nozzle 462, the second nozzle 464, and the added nozzle are supported by different arms 461, respectively, and these arms 461 may be moved independently. Optionally, the first nozzle 462, the second nozzle 464, and the added nozzle may be mounted on the same arm and moved simultaneously.

The exhaust unit 470 includes an environmental exhaust unit 471 and a process exhaust unit 472. The environmental exhaust unit 471 exhausts the inner space U. The environmental exhaust unit 471 is installed under the housing 410. A plurality of environmental exhaust units 471 may be provided. The process exhaust unit 472 exhausts the treatment space P. The process exhaust unit 472 is installed under the cup body 420. The process exhaust unit 472 may be installed to penetrate the lower wall 410c of the housing 410.

The lifting unit 480 moves the cup body 420 in the up and down direction. The relative height between the cup body 420 and the substrate W is changed by the vertical movement of the cup body 420. Accordingly, since the cups 422, 424, and 426 for recovering the treatment liquid are changed according to the type of the liquid supplied to the substrate W, the liquids may be separated and recovered. Also, the lifting unit 480 may move the partition plate 430 in the up and down direction. The lifting unit 480 may include a plurality of lifting drivers. Unlike the above description, the cup body 420 is fixedly installed, and the lifting unit 480 may move the support unit 440 in the up and down direction.

The controller 500 controls the airflow supply unit 450, the liquid supply unit 460, and the lifting unit 480. Hereinafter, a method of treating a substrate by using the controller 500 will be described.

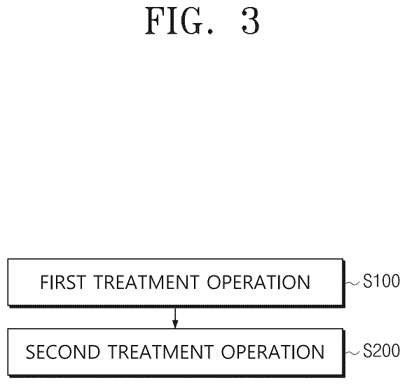

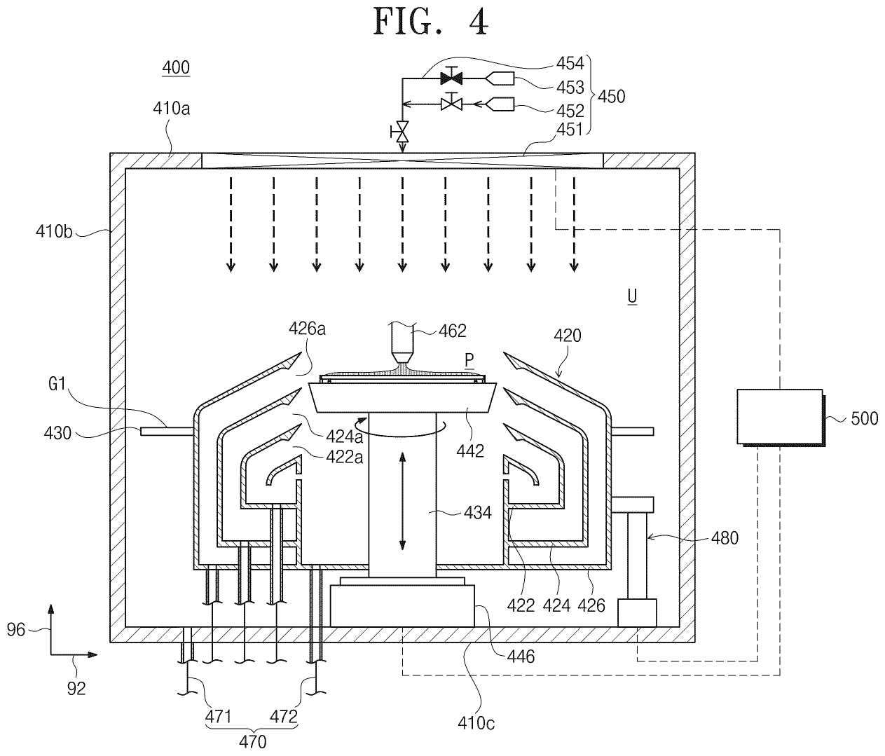

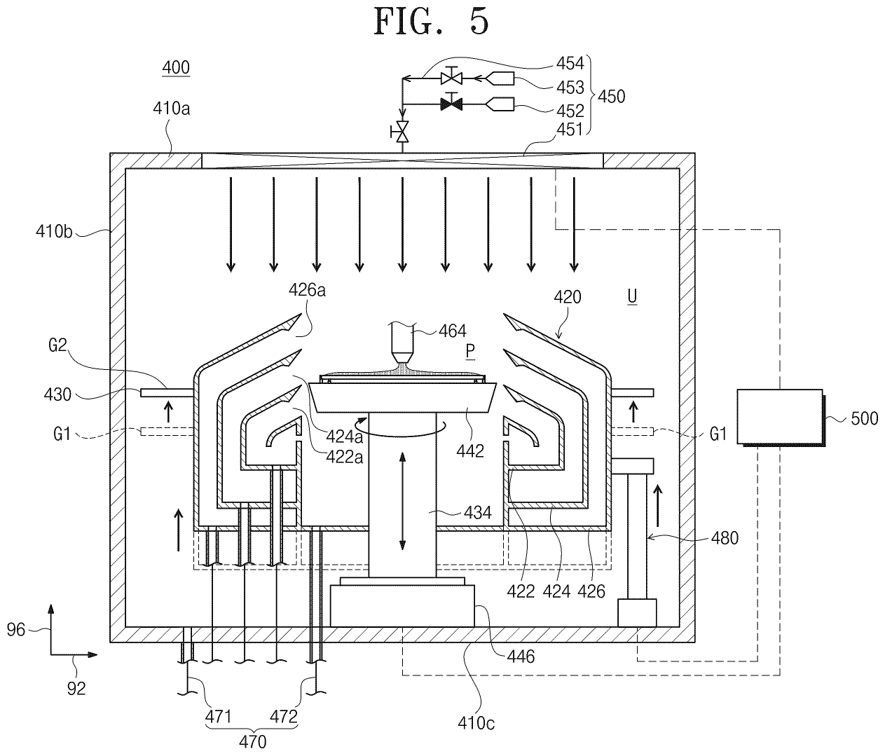

FIG. 3 is a flowchart illustrating a substrate processing method according to an exemplary embodiment of the present invention. Referring to FIG. 3, the substrate processing method includes a first treatment operation S100 and a second treatment operation S200. FIG. 4 is a cross-sectional view illustrating a cross-section of the liquid treating chamber in a first treatment operation, and FIG. 5 is a cross-sectional view illustrating a cross-section of the liquid treating chamber in a second treatment operation.

Referring to FIG. 4, in the first treatment operation S100, the substrate W is liquid-treated with a first treatment liquid. The first nozzle 462 supplies the first treatment liquid onto the substrate W. The airflow supply unit 450 supplies first gas. The first gas forms a descending airflow in the inner space U. The partition plate 430 is located at a first position G1. The first position G1 may be a position at which the partition plate 430 is not raised. Alternatively, when the partition plate 430 is fixed to the outer cup 426, the first position G1 may be a position at which the partition plate 430 is not raised or a position at which the treatment liquid is recovered to the outer cup 426.

Referring to FIG. 5, in the second treatment operation S100, the substrate W is liquid-treated with a second treatment liquid. The liquid supply unit 460 supplies the second treatment liquid onto the substrate W through the second nozzle 464. The airflow supply unit 450 supplies second gas. The second gas forms descending airflow in the inner space U. The partition plate 430 is located at a second position G2. The second position G2 is a position where the partition plate 430 is raised in the third direction 96. The second position G2 is higher than the first position G1. The second position G2 is a position where the volume of the upper space U1 is reduced.

According to the exemplary embodiment of the present invention, by providing the partition plate 430, it is possible to induce the descending airflow to be exhausted to the process exhaust unit 472 rather than the environmental exhaust unit 471, thereby preventing impurities, such as fumes, generated during substrate treatment from being discharged to the outside. In addition, by moving the partition plate 430 to the second position G2, the atmosphere replacement speed of the inner space U may be improved. When IPA is provided as the second treatment liquid, particles may be generated on the substrate W as the drying time of the IPA increases. Accordingly, in order to prevent generation of particles, the drying speed of the IPA needs to be improved by rapidly replacing the atmosphere of the inner space U with an atmosphere of low humidity. When the partition plate 430 is located at the second position G2, the volume of the upper space U1 is reduced, and thus, the speed and the exhaust speed of the descending air flowing into the treatment space P may be increased. Accordingly, the atmosphere replacement speed may be improved, and generation of particles may be suppressed by reducing the drying time of the IPA.

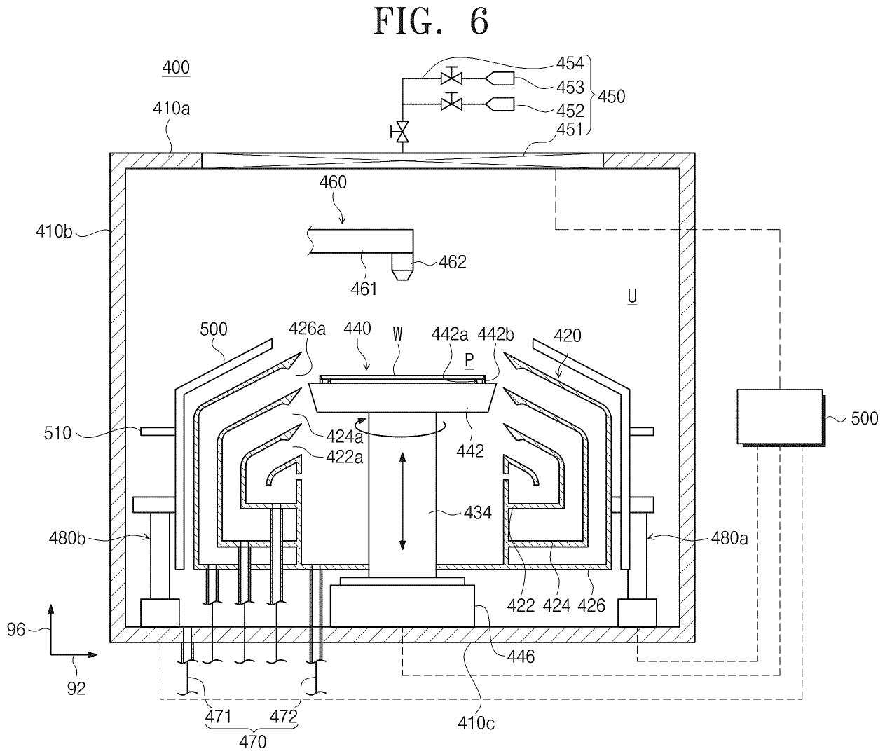

In the above-described example, the present invention has been described based on the case where the partition plate 430 is provided independently or installed on the sidewall 426b of the outer cup 426 as an example. However, the present invention is not limited thereto, and an auxiliary cup 500 with an open top surrounding the cup body 420 is provided as shown in FIG. 6, the partition plate 510 is installed outside the auxiliary cup 500, and the lifting unit 480 may be provided to raise and lower the auxiliary cup.

Furthermore, in the above example, the present invention has been described based on the case where the cup body 420 is integrally provided and is integrally driven by the lifting unit 480. However, the present invention is not limited thereto, and the inner cup 422, the intermediate cup 424, and the outer cup 426 are separately provided to the cup body 420, and the lifting unit 480 may individually drive the inner cup 422, the intermediate cup 424, and the outer cup 426.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

1. An apparatus of processing a substrate, the apparatus comprising:
a housing providing an inner space;
a cup body that is provided in the inner space and has a treatment space with an open top;
a support unit for supporting a substrate in the treatment space;
an airflow supply unit installed on an upper wall of the housing and supplying descending airflow to the inner space and the treatment space;
a lifting unit for changing a relative height between the substrate supported by the support unit and the cup body;
a liquid supply unit for supplying a treatment liquid to the substrate supported by the support unit;
an exhaust member for exhausting the inner space and the treatment space; and
a partition plate that divides the inner space into an upper space and a lower space and is provided to be movable in an up and down direction.

2. The apparatus of claim 1, wherein the partition plate is fixedly installed on an outer wall of the cup body to be raised and lowered together with the cup body, and extends from the outer wall of the cup body toward a sidewall of the housing.

3. The apparatus of claim 2, wherein a passage through which the descending airflow flows is formed between the partition plate and the sidewall of the housing.

4. The apparatus of claim 2, wherein the partition plate is provided as a blocking plate in which a hole penetrating the partition plate vertically is not formed.

5. The apparatus of claim 2, wherein the partition plate is provided in a ring shape.

6. The apparatus of claim 2, wherein the airflow supply unit is provided to selectively supply descending airflow of first gas and descending airflow of second gas,
the second gas is gas with lower humidity than the first gas,
the liquid supply unit includes:
a first nozzle that supplies a first treatment liquid; and
a second nozzle that supplies a second treatment liquid, and
the apparatus further includes a controller for controlling the airflow supply unit, the liquid supply unit, and the lifting unit.

7. The apparatus of claim 6, wherein when the liquid supply unit discharges the first treatment liquid, the controller positions the partition plate at a first position and controls the liquid supply unit, the lifting unit, and the airflow supply unit to supply the descending airflow of the first gas, and
when the liquid supply unit discharges the second treatment liquid, the controller positions the partition plate at a second position, and controls the liquid supply unit, the lifting unit, and the airflow supply unit to supply the descending airflow of the second gas, and
the second position is higher than the first position.

8. The apparatus of claim 7, wherein the first treatment liquid is acidic chemical or pure water, and
the second treatment liquid is an organic solvent.

9. The apparatus of claim 8, wherein the organic solvent is isopropyl alcohol.

10. The apparatus of claim 1, further comprising:
an auxiliary cup surrounding the cup body and having an open top,
wherein the partition plate is fixedly installed on an outer wall of the auxiliary cup so as to be raised and lowered together with the auxiliary cup, and extends from the outer wall of the auxiliary cup toward a sidewall of the housing, and
the lifting unit raises and lowers the auxiliary cup.

11. The apparatus of claim 10, wherein when the liquid supply unit discharges the first treatment liquid, the controller positions the partition plate at a first position and controls the liquid supply unit, the lifting unit, and the airflow supply unit to supply descending airflow of first gas, and
when the liquid supply unit discharges the second treatment liquid, the controller positions the partition plate at a second position, and controls the liquid supply unit, the lifting unit, and the airflow supply unit to supply descending airflow of second gas, and
the second position is higher than the first position.

12. The apparatus of claim 10, wherein the auxiliary cup is coupled to the cup body.

13-16. (canceled)

17. An apparatus of processing a substrate, the apparatus comprising:
a housing providing an inner space;
a cup body that is provided in the inner space and has a treatment space with an open top;
a support unit for supporting a substrate in the treatment space;
an airflow supply unit installed on an upper wall of the housing and supplying descending airflow to the inner space and the treatment space;
a lifting unit for changing a relative height between the substrate supported by the support unit and the cup body;
a liquid supply unit for supplying a treatment liquid to the substrate supported by the support unit;
an exhaust member for exhausting the inner space and the treatment space;
a partition plate that divides the inner space into an upper space and a lower space and is provided to be movable in an up and down direction; and
a controller for controlling the airflow supply unit, the liquid supply unit, and the lifting unit,
the partition plate is provided in a ring shape, is fixedly installed on an outer wall of the cup body to be raised and lowered together with the cup body, extends from the outer wall of the cup body toward a sidewall of the housing, and is formed with a passage through which the descending airflow flows between the partition plate and the sidewall of the housing,
the liquid supply unit includes:
a first nozzle that supplies a first treatment liquid; and
a second nozzle that supplies a second treatment liquid, and
the airflow supply unit is provided to selectively supply descending airflow of first gas and descending airflow of second gas,
the second gas is gas with lower humidity than the first gas.

18. The apparatus of claim 17, wherein when the liquid supply unit discharges the first treatment liquid, the controller positions the partition plate at a first position and controls the liquid supply unit, the lifting unit, and the airflow supply unit to supply the descending airflow of the first gas, and
when the liquid supply unit discharges the second treatment liquid, the controller positions the partition plate at a second position, and controls the liquid supply unit, the lifting unit, and the airflow supply unit to supply the descending airflow of the second gas, and
the second position is higher than the first position.

19. The apparatus of claim 18, wherein the first treatment liquid is acidic chemical or pure water, and
the second treatment liquid is an organic solvent.

20. The apparatus of claim 18, further comprising:
an auxiliary cup surrounding the cup body and having an open top,
wherein the auxiliary cup is coupled to the cup body,
the partition plate is fixedly installed on an outer wall of the auxiliary cup, and extends from the outer wall of the auxiliary cup toward the sidewall of the housing, and
when the liquid supply unit discharges the first treatment liquid, the controller positions the partition plate at a first position and controls the liquid supply unit, the lifting unit, and the airflow supply unit to supply the descending airflow of the first gas, and
when the liquid supply unit discharges the second treatment liquid, the controller positions the partition plate at a second position, and controls the liquid supply unit, the lifting unit, and the airflow supply unit to supply the descending airflow of the second gas, and
the second position is higher than the first position,
the first treatment liquid is acidic chemical or pure water, and
the second treatment liquid is an organic solvent.
